(19) United States
(12) Patent Application Publication
(10) Pub. No.: US 2017/0259366 A1
(43) Pub. Date: Sep. 14, 2017

(54) LEAD-FREE SOLDER BUMP JOINING STRUCTURE

(71) Applicants: NIPPON STEEL & SUMIKIN MATERIALS CO., LTD., Tokyo (JP); NIPPON MICROMETAL CORPORATION, Saitama (JP)

(72) Inventors: Shinji ISHIKAWA, Tokyo (JP); Shinichi TERASHIMA, Tokyo (JP); Keisuke AKASHI, Saitama (JP)

(21) Appl. No.: 15/529,637

(22) PCT Filed: Oct. 30, 2015
(86) PCT No.: PCT/JP2015/080647

§ 371 Date: May 25, 2017

(30) Foreign Application Priority Data
Nov. 27, 2014 (JP) 2014-240113

(51) Int. Cl. B23K 1/20; B23K 35/30; C22C 13/02; B23K 1/19

(52) U.S. Cl. CPC B23K 1/20; B23K 1/19; B23K 35/302; C22C 13/02; H01L 2021/60022

(57) ABSTRACT

In a lead-free solder bump, diffusion of Cu from intermetallic compound layers, which are respectively formed at joining interfaces with Cu electrodes is suppressed, so that the in metallic compound layers are not likely to disappear. Correspondingly, with the use of the intermetallic compound layers, Cu is not likely to diffuse from the Cu electrodes into the lead-free solder bump. Even when an electric current flows continuously between a first electronic member and a second electronic member through the lead-free solder bump, the occurrences of the electromigration phemenon and the thermomigration phenomenon are suppressed. Thus, the present invention provides a lead-free solder bump joining structure capable of suppressing the disconnection failure caused by the synergistic effect of the electromigration phenomenon and the thermomigration phenomenon.

### TECHNICAL FIELD

The present invention relates to a lead-free solder bump joining structure, and is suitable for, for example, a lead-free bump joining structure in which a copper electrode (hereinafter, referred to as the Cu electrode) of a first electronic member and a Cu electrode of a second electronic member are joined with each other with a lead-free solder.

### BACKGROUND ART

As a method for electrically connecting electronic members in, for example, electronic devices, there has been known a method using protrusions, referred to as bumps, formed on electrodes. Recently, for example, because of environmental issues and the RoHS instruction (Restriction of the Use of Certain. Hazardous Substances in Electrical and Electronic Equipment) of EU (European Union), lead-free solder alloys not containing Pb but mainly composed of Sn have been frequently adopted as the bumps formed on Cu electrodes (for example, see Patent Literature 1).

In addition, recently, along with the miniaturization and high functionalization of electronic devices, high-density mounting has been required in semiconductor mounting. Accordingly, flip-chip mounting advantageous for high-density mounting has been rapidly adopted, and recently, electrode pitches as narrow as 200 [μm] or less have been required. Such narrow pitches require bumps to be miniaturized; however, recently achieved high performances of chips caused the increases in the electric current magnitudes.

### CITATION LIST

### Patent Literature

Patent Literature 1: Japanese Patent Laid-Open No. 05-50286

### SUMMARY OF INVENTION

### Technical Problem

However, in the joining portions (hereinafter, also simply referred to as lead-free solder bumps) made of a lead-free solder alloy between electronic members, when the electric current (electric current density) flowing per unit area increases, the electromigration phenomenon (hereinafter, also referred to as the EM phenomenon) of Cu or Sn occurs in the lead-free solder bump, and there is an apprehension that eventually disconnection failure is caused.

Conventionally, it has been known that the EM phenomenon may occur in cases where an electrode pitch is narrow, for example, 200 [μm] or less. For example, the occurrence of the EM phenomenon was verified in the case where the diameter of the Cu electrode was 100 [μm] at the position where the Cu electrode joined to a lead-free solder bump, and the electric current density was as large as 10×10³ [A/cm²] or more. However, even when the electrode pitch was as wide as 400 [μm] and the diameter of the Cu electrode at the position where the Cu electrode joined to a lead-free solder bump was 200 [μm], defects occurred in several lead-free solder bumps of a plurality of the lead-free solder bumps, and hence the present inventors have reached a consideration that the EM phenomenon alone cannot cause defects in the lead-free solder bumps.

Hereinafter, the verification test that led to the above-described consideration is specifically described. FIG. 4A shows a verification circuit used to verify what were the states of the lead-free solder bump joining structures 101a to 101f in the case where a wide electrode pitch of 400 [μm] or more was adopted, the diameters of the Cu electrodes 4 and 7 at the positions joining to the lead-free solder bumps 110a to 110f were selected to be 200 [μm] or more, and the electric current density was set at a lower electric current density than the electric current density of 10×10³ [A/cm²] being assumed to cause the EM phenomenon. In the verification circuit 100, six lead-free solder bump joining structures 101a to 101f were electrically connected to each other, and an electric current having a small current density was supplied to the Cu electrode 4 of the first electronic member, beneath the lead-free solder bump 110a at one end. Thus the electric current was applied in the order of the lead-free solder bump 110a, the Cu electrode 7 of the second electronic member, the lead-free solder bump 110b, the Cu electrode 4 of the first electronic member, the lead-free solder bump 110c, the Cu electrode 7 of the second electronic member, the lead-free solder bump 110d, the Cu electrode 4 of the first electronic member, the lead-free solder bump 110e, the Cu electrode 7 of the second electronic member, the lead-free solder bump 110f, and the Cu electrode 4 of the first electronic member.

FIG. 4B shows the results obtained when an electric current having a small electric current density was applied from the lead-free solder bump joining structure 101a at one end to the lead-free solder bump joining structure 101f at the other end over a long period of time as described above, and then the internal states of the lead-free solder bump joining structures 101a to 101f were examined with the metallurgical microscope photographs. As shown in FIG. 4B, it was verified that in each of the lead-free solder bumps 110a, 110c, 110d, and 110e, the Cu electrode 4 was present, and moreover, an intermetallic compound (IMC: Inter-Metallic Compound) layer 104, which functions as a barrier layer, was formed in the joining interface with the Cu electrode 4. On the other hand, it was verified that in the lead-free solder bumps 110b and 110f, the Cu electrodes 4 and the intermetallic compound layers 104 obviously disappeared, and the Cu electrodes 4 were replaced with the lead-free solder bumps 110b and 110f,

Here, it is considered that in the lead-free solder bumps 110b and 110f situated at the ends of the lead-free solder bumps 110b, 110d and 110f, in each of which the electric current flows from the upper Cu electrode 7 to the lower Cu electrode 4, the temperature is high and a large temperature gradient is generated internally in the lower Cu electrode, into which the electric current flows, and in the IMC layer formed initially in the joining interface with the Cu electrode. Consequently, Cu migrates from the higher temperature region to the lower temperature region (in the figure, the arrows indicate the direction of Cu migration), and on the other hand, Sn migrates from the lower temperature region to the higher temperature region; Cu is consumed in the IMC layer and the lower Cu electrode each being at a higher temperature. Eventually the IMC layer and the lower Cu electrode are replaced entirely with the lead-free solder bump 110b (110f).

In other words, it is considered that when the temperature gradient occurs, Cu migrates from the higher temperature region to the lower temperature region, and Sn migrates from the lower temperature region to the higher temperature region. Accordingly, in the lead-free solder bump joining structure 101b (101f) having a temperature gradient, Cu in the IMC layer, which is located on the lower side, at a higher temperature migrates into the lead-free solder bump 110b (110f) at a lower temperature, in addition to the migration of Cu from the lower side to the upper side due to the EM phenomenon. Thereby, the thickness of the IMC layer is gradually decreased. In this case, in the lead-free solder bump joining structure 101b (101f), Cu in the lower Cu electrode also migrates into the IMC layer, thus the thickness of the Cu electrode is decreased, and at the same time the Sn in the lead-free solder bump 110b (110f) migrates into the lower. Cu electrode at a higher temperature. Thus the IMC layer on the lower side disappears, and the Cu in the lower Cu electrode migrates into the lead-free solder bump 110b (110f), and the Sn in the lead-free solder bump 100b (110f) enters the position of the Cu electrode.

Consequently, as shown in FIG. 5, for example, in the lead-free solder bump joining structure 101b, it can be considered that a state occurs in which the Cu electrode 4 apparently disappears, and the region ER1 in which the Cu electrode 4 has been formed is replaced with the lead-free solder bump 110b. When the thin Cu electrode between the first electronic member 2 and the lead-free solder bump 110b is replaced entirely with. Sn as described above, the resistance is increased in the lead-free solder bump joining structure 101b, resulting in excessive heat generation. Eventually the lead-free solder bump 110b is melted and disconnection failure is likely to occur.

The above-described phenomenon in which the element(s) migrates due to temperature gradient is generally referred to as the thermomigration phenomenon (hereinafter, also referred to as the TM phenomenon). Generally, it is considered that the TM phenomenon occurs simultaneously with the EM phenomenon when a large electric current flows because the temperature gradient due to the heat generation (Joule heat) is likely to occur when a large electric current, which facilitates the occurrence of the EM phenomenon, flows through the wiring of a semiconductor device.

The present inventors have verified that even when a relatively low electric current having an electric current density of 3×10³ [A/cm²] flows in the lead-free solder bump 110b formed between the Cu electrode 4 of the first electronic member 2 and the Cu electrode 7 of the second electronic member 5, the Cu electrode 4 into which electrons flow is gradually consumed, and the Cu electrode 4 is being replaced with the lead-free solder bump 110b, and consequently the resistance is increased, resulting in disconnection due to melting. From this verification, it has been inferred that although a relatively low electric current density has a small effect in promoting the diffusion of Cu and Sn caused by the EM phenomenon, the effect of migration of Cu and Sn caused by the TM phenomenon has been added. It has been discovered that even with a relatively low electric current density of, for example, 3×10³ [A/cm²], the diffusion of Cu is drastically promoted due to the synergistic effect of the EM phenomenon and the TM phenomenon, and disconnection failure occurs in the lead-free solder bump 110b.

The present invention has been achieved in view of such problems as described above, and an object of the present invention is to provide a lead-free solder bump joining structure capable of suppressing the disconnection failure caused by the synergistic effect of the electromigration phenomenon and the thermomigration phenomenon.

### Solution to Problem

The lead-free solder bump joining structure according to a first aspect of the present invention is a lead-free solder bump joining structure joining a copper electrode of a first electronic member and a copper electrode of a second electronic member through a lead-free solder bump. An electric current having an electric current density of 0.7×10³ [A/cm²] or more flows between the first electronic member and the second electronic member through the lead-free solder bump. The lead-free solder bump comprises X including any one or any two or more of Ni, Co, Pd, Au and Pt in a content of 0.03 to 0.32% by mass in total and the balance composed of Sn and inevitable impurities. In the lead-free solder bump, an intermetallic compound layer composed of (Cu, X) ₆Sn₅ including the X is formed in a joining interface with the copper electrode of the first electronic member and in a joining interface with the copper electrode of the second electronic member.

### Advantageous Effects of Invention

According to the lead-free solder bump joining structure of the present invention, the diffusion of Cu from the intermetallic, compound layers formed in the joining interfaces with the Cu electrodes into the lead-free solder bump is suppressed and the intermetallic compound layers are not likely to disappear. Due to the intermetallic compound layers, Cu is not likely to diffuse from the Cu electrodes into the lead-free solder bump. Accordingly even when an electric current flows continuously between the first electronic member and the second electronic member through the lead-free solder bump, the occurrences of the electromigration phenomenon and the thermomigration phenomenon are suppressed; and thus, it is possible to provide a lead-free solder bump joining structure capable of suppressing the disconnection failure caused by the synergistic effect of the electromigration phenomenon and the thermomigration phenomenon.

### BRIEF DESCRIPTION OF DRAWINGS

FIG. 1 is a schematic diagram illustrating the cross-sectional structure of the lead-free solder bump joining structure of the present invention;

FIG. 2A is a metallurgical microscope photograph showing the cross-sectional structure of the lead-free solder bump joining structure of the present invention after an elapsed time of 100 hours, and FIG. 2B is a metallurgical microscope photograph showing the cross-sectional structure of the lead-free solder bump joining structure of the present invention after an elapsed time of 200 hours;

FIG. 3A is a metallurgical microscope photograph showing the cross-sectional structure of a conventional lead-free solder bump joining structure after an elapsed time of 100 hours, and FIG. 3B is a metallurgical microscope photograph showing the cross-sectional structure of the conventional lead-free solder bump joining structure after an elapsed time of 200 hours;

FIG. 4A is a schematic diagram illustrating the overall configuration of a verification circuit, and FIG. 4B is a set of metallurgical microscope photographs showing the cross-sectional structures in the respective lead-free solder bump joining structures in the verification circuit; and

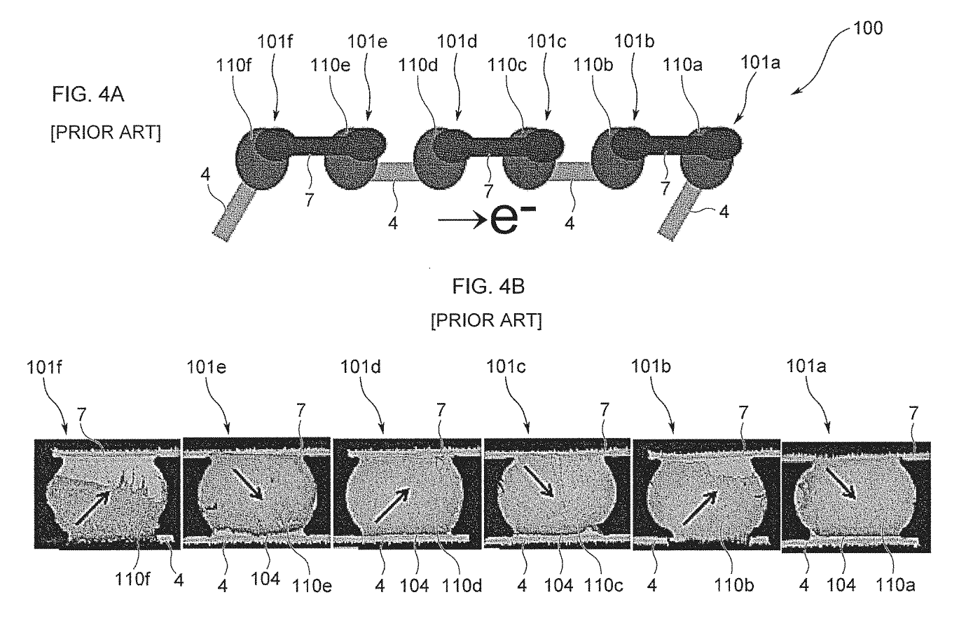

FIG. 5 is a schematic diagram showing the cross-sectional structure of the lead-free solder bump joining structure having a large temperature gradient shown in FIG. 4, after a predetermined elapsed time.

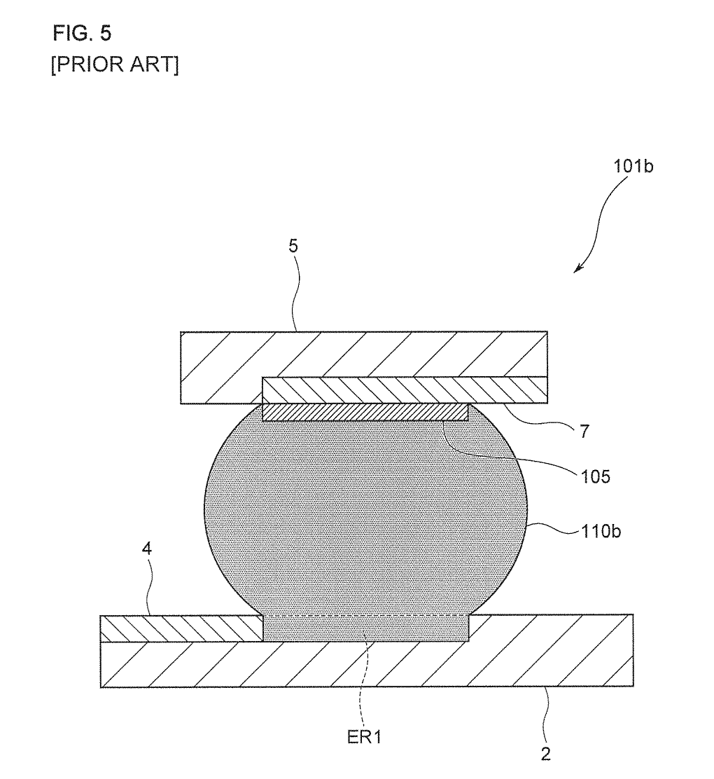

### DESCRIPTION OF EMBODIMENTS

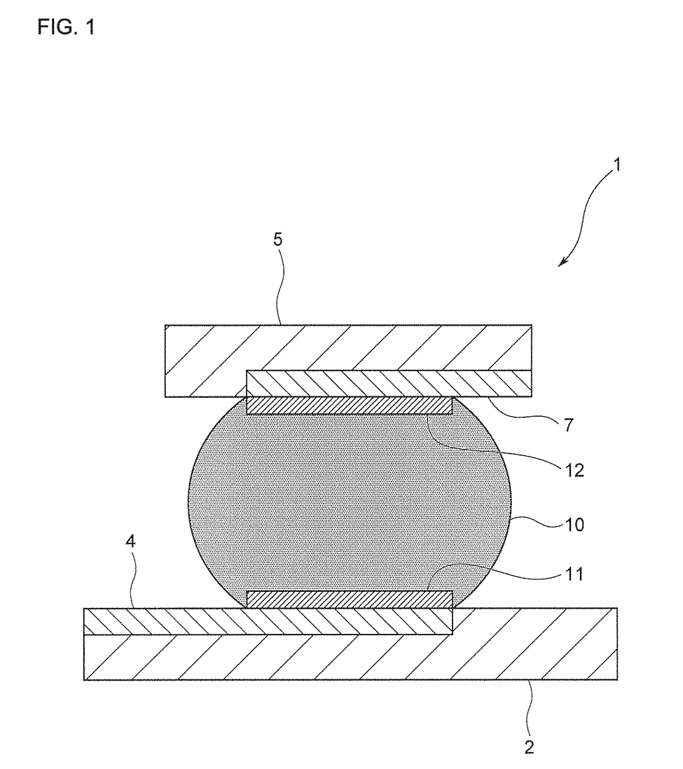

As shown in FIG. 1, in a lead-free solder bump joining structure 1 of the present invention, a lead-free solder bump 10 made of a lead-free solder alloy is formed between a Cu (copper) electrode 4 of a first electronic member 2 and a Cu electrode 7 of a second electronic member 5. The Cu electrodes 4 and 7 facing each other are physically and electrically joined to each other through the lead-free solder bump 10. The lead-free solder bump joining structure 1 of the present invention is different from conventional lead-free solder bump joining structures in that intermetallic compound (IMC: Inter Metallic Compound) layers 11 and 12, each functioning as a barrier layer, respectively formed in the joining interfaces with the Cu electrodes 4 and 7 in the lead-free solder bump 10 are being continuously formed without disappearing even when an electric current is continuously supplied over a long period of time, and the intermetallic compound layers 11 and 12 suppress the disconnection failure caused by electromigration phenomenon (EM phenomenon) or thermomigration phenomenon (TM phenomenon).

In particular, the lead-free solder bump joining structure 1 of the present invention is used in an electric circuit using an electric current having an electric current density of 0.7×10³ [A/cm²] or more, an electric current of 1.0×10³ [A/cm²] or more, or, an electric current having an electric current density of 10×10³ [A/cm²] or more, in which the disconnection failure tend to occur through the synergistic effect of the electromigration phenomenon and the thermomigration phenomenon. Even when such a current flows between the first electronic member 2 and the second electronic member 5 through the lead-free solder bump 10, the lead-free solder bump joining structure 1 of the present invention suppresses the disconnection failure caused by the synergistic effect of the electromigration phenomenon and the thermomigrat ion phenomenon.

The present inventors made a continuous investigation on the countermeasure for the occurrence of the disconnection failure due to the synergistic effect of the electromigration phenomenon and the thermomigration phenomenon, and consequently have revealed that the occurrence of the disconnection failure in the lead-free solder bump joining structure 1 is remarkably suppressed by controlling the formation of the intermetallic compound layers 11 and 12.

The lead-free solder bump joining structure 1 of the present invention is different from a conventional lead-free solder bump joining structure having the intermetallic compound layers made from Cu₆Sn₅ in that the lead-free solder bump joining structure 1 of the present invention includes the intermetallic compound layers 11 and 12 each composed of substitutional solid solution (Cu, X) ₆Sn₅ obtained by substituting Cu by a specific element X at the position(s) of Cu in Cu₆Sn₅. Hence, the time until the occurrence of the disconnection failure is remarkably prolonged as compared with that of the conventional lead-free solder bump joining structure. The lead-free solder bump joining structure 1 of the present invention does not include a conventional intermetallic compound layer composed of Cu₆Sn₅ or Cu₃Sn, but includes the intermetallic compound layers 11 and 12 each composed of (Cu, X) ₆Sn₅. It is inferred that due to the intermetallic compound layers 11 and 12 each composed of (Cu, X) ₆Sn₅, the migration of Cu in the intermetallic compound layers 11 and 12 is suppressed. Consequently, the rate of the consumption (thickness reduction) of the intermetallic compound layers 11 and 12 caused by the diffusion of Cu is decreased, and the time until the disappearance of the intermetallic compound layers 11 and 12 is prolonged.

Specifically, in the course of the production process of the lead-free solder bump 10, a few percent of the element X replaces the position(s) of Cu in Cu₆Sn₅ having a crystal structure, and consequently the intermetallic compound layers 11 and 12, each composed of (Cu, X) ₆Sn₅, are respectively formed along the joining interfaces with the Cu electrodes 4 and 7. Thereby, in the lead-free solder bump joining structure 1, the defect concentration contributing to the diffusion of Cu is decreased in the intermetallic compound layers 11 and 12 formed in the joining interfaces with the Cu electrodes 4 and 7 in the lead-free solder bump 10. The diffusion of Cu from the intermetallic compound layers 11 and 12 into the lead-free solder bump 10 is suppressed, and the diffusion of Cu from the Cu electrodes 4 and 7 into the lead-free solder bump 10 is also suppressed.

In order to efficiently obtain the intermetallic compound composed of (Cu, X) ₆Sn₅ in the joining interfaces with the Cu electrodes 4 and 7 in the lead-free solder bump 10, it is preferable to prepare a composition including X and the balance (remainder) composed of Sn and inevitable impurities. X is one or two or more of Ni, Co, Pd, Au and Pt, and capable of drastically suppressing the diffusion of Cu through substituting for Cu and forming a substitutional solid solution. The total content of X is 0.03 to 0.32% by mass.

It is not preferable in a case where the content of X is less than 0.03% by mass because the concentrations of X in the intermetallic compound layers 11 and 12 each composed of (Cu, X) ₆ n₅ are decreased and the contribution of X to the decrease of the defect concentration is insufficient in the joining interfaces with the Cu, electrodes 4 and 7 in the lead-free solder bump 10. On the contrary, the content of X exceeding 0.32% by mass is also unpreferable because the concentrations of X in the intermetallic compounds 11 and 12 are too high. This may increase the defect concentration or the X incapable of forming a substitutional solid solution in the intermetallic compounds 11 and 12 disturb the formation of the uniform intermetallic compounds.

For example, when. X is composed of a single element such as Ni, the lead-free solder bump 10 contains Ni in a content of 0.03 to 0.32% by mass, preferably 0.03 to 0.15% by mass, and the balance composed. of Sn and inevitable impurities. The intermetallic compound layers 11 and 12, each composed of (Cu, Ni) ₆Sn₅, are formed in the joining interface with the Cu electrode 4 of the first electronic member 2 and in the joining interface with the Cu electrode 7 of the second electronic member 5, respectively. Consequently, in the lead-free solder bump 10 containing Ni, due to the intermetallic compound layers 11 and 12 each composed of (Cu, Ni) ₆Sn₅, the occurrence of the electromigration phenomenon is suppressed, and moreover, the occurrence of the thermomigration phenomenon is suppressed, and thus the conventional disconnection failure caused by the synergistic effect of the electromigration phenomenon and the thermomigration phenomenon is suppressed.

When X is any one of Co, Pd, Au and Pt, other than Ni, the lead-free solder bump 10 has a composition including any one of Co, Pd, Au and Pt in a content of 0.03 to 0.32% by mass, preferably 0.10 to 0.25% by mass and the balance composed of Sn and inevitable impurities. In this case, in the lead-free solder bump 10, it is possible to form the intermetallic compound layers 11 and 12 each composed of a substitutional solid solution (Cu, Co) ₆Sn₅, (Cu, Pd) ₆Sn₅, (Cu, Au) ₆Sn₅ or (Cu, Pt) ₆Sn₅, in each of which the specific element X substitutes for Cu at the position(s) of Cu in Cu₆Sn₅, depending on the type of the added element X. The intermetallic compound layers 11 and 12 are formed in the joining interface with the Cu electrode 4 of the first electronic member 2 and the joining interface with the Cu electrode 7 of the second electronic member 5.

Consequently, due to the intermetallic compound layers 11 and 12 containing the added element X in the lead-free solder bump 10 including any one of Co, Pd, Au and Pt, other than. Ni, the occurrences of the electromigration phenomenon and the thermomigration phenomenon are further suppressed and the conventional disconnection failure caused by the synergistic effect of the electromigration phenomenon and the thermomigration phenomenon is further suppressed, as compared with the case of the lead-free solder bump 10 to which Ni is added.

When X is a set of any two of Co, Pd, Au and Pt, other than Ni, the lead-free solder bump 10 has a composition containing any two of Co, Pd, Au and Pt in a content of 0.03 to 0.32% by mass in total, preferably 0.10 to 0.25% by mass in total, and the balance composed of Sn and inevitable impurities. In this case, in the lead-free solder bump 10, it is possible to form the intermetallic compound layers 11 and 12 in each of which two types of X simultaneously substitute to form a substitutional solid solution, depending on the types of the added elements X. The intermetallic compound layers 11 and 12 are formed in the joining interface with the Cu electrode 4 of the first electronic member 2 and the joining interface with the Cu electrode 7 of the second electronic member 5. For example, when Co and Pd are added as X, the intermetallic compound layers 11 and 12 each composed of substitutional solid solution (Cu, Co+Pd) ₆Sn₅, in which Co or Pd substitutes for Cu at the position(s) of Cu in Cu₆Sn₅, are formed in the joining interface with the Cu electrode 4 of the first electronic member 2 and the joining interface with the Cu electrode 7 of the second electronic member 5.

Due to the intermetallic compound layers 11 and 12 containing the added elements X, the lead-free solder bump 10 including any two of Co, Pd, Au and Pt and excluding Ni further suppresses the occurrences of the electromigration phenomenon, thermomigration phenomenon, and the conventional disconnection failure caused by the synergistic effect of the electromigration phenomenon and the thermomigration phenomenon, as compared with the case of the lead-free solder bump 10 to which Ni has been added.

When X is a set of Ni and any one or any two or more of Co, Pd, Au and Pt, the lead-free solder bump 10 has a composition including Ni and any one or any two or more of Co, Pd, Au and Pt in a content of 0.03 to 0.32% by mass in total, preferably 0.14 to 0.32% by mass in total, and the balance composed of Sn and inevitable impurities. In this case, in the lead-free solder bump 10, it is possible to form the intermetallic compound layers 11 and 12 each composed of substitutional solid solution (Cu, Ni+(Co, Pd, Au, Pd)) ₆Sn₅, in which Ni or any one of Co, Pd, Au and Pt substitutes for Cu at the position(s) of Cu in Cu₆Sn₅. The intermetallic compound layers 11 and 12 are formed in the joining interface with the Cu electrode 4 of the first electronic member 2 and the joining interface with the Cu electrode 7 of the second electronic member 5.

Consequently, due to the intermetallic compound layers 11 and 12 containing the added element X, the lead-free solder bump 10 including any one or any two or more of Co, Pd, Au and Pt in addition to Ni further suppresses the occurrences of the electromigration phenomenon, the thermomigration phenomenon, and the conventional disconnection failure caused by the synergistic effect of the electromi ration phenomenon and the thermomigration phenomenon, as compared with the above-described lead-free solder bump 10 including only Ni or the above-described lead-free solder bump 10 including only one of Co, Pd, Au and Pt.

The observation of (Cu, X) ₆Sn₅ in the lead-free solder bump 10 is performed by using a metallurgical microscope or a SEM (Scanning Electron Microscope). In a case where the presence of (Cu, X) ₆Sn₅ is observed at a magnification of approximately 1000 to 5000, the above-described effects are obtained. The identification of (Cu, X) ₆Sn₅ is performed on the basis of the analysis of the electron beam diffraction pattern observed with a TEM (Transmission Electron Microscope).

In the lead-free solder bump joining structure 1 of the present invention, the lead-free solder bump 10 having the above-described composition may include, as necessary, any one or any two or more of Ag, Cu and Bi in a content of 0.1 to 7.0% by mass in total. When the total content of any one or any two or more of Ag, Cu and Bi is less than 0.1% by mass, the TCT property is insufficient, which is not preferable. When the total content of any one or any two or more of Ag, Cu and Bi exceeds 7.0% by mass in total, the drop shock reliability is insufficient, which is not preferable.

In this case, the lead-free solder bump 10 has a composition including X, which includes any one or any two or more of Ni, Co, Pd, Au and Pt, in a content of 0.03 to 0.32% by mass in total, and further including any one or any two or more of Ag, Cu and Bi in a content of 0.1 to 7.0% by mass in total, and. the balance composed of Sn and inevitable impurities.

The lead-free solder bump 10 including, in addition to X, any one or any two or more of Ag, Cu and Si in a content of 0.1 to 7.0% by mass in total suppress the conventional disconnection failure caused by the synergistic effect of the electromigration phenomenon and the thermomigration, and improves the TOT (Thermal. Cycling Test) property. In particular, the lead-free solder bump 10 including, in addition to Bi, any one or two of Ag and Cu further improves the TOT property.

In addition, in the lead-free solder bump joining structure 1 of the present invention, the lead-free solder bump 10 may include, as necessary, any one or any two or more of. Ng, P and Ge in a content of 0.0001 to 0.108% by mass in total. When the total content of any one or any two or more of Mg, P and Ge is less than 0.0001% by mass, the occurrence of voids cannot be suppressed due to temporal changes, which is not preferable. When the total content of any one or any two or more of Mg, P and Ge exceeds 0.108% by mass, failure (for example, a non-spherical ball) tends to occur, which is not preferable, in the production of the lead-free ball, which is to be the lead-free solder bump 10.

Specifically, the lead-free solder bump 10 including any one or any two or more of Mg, P and Ge may have a composition containing the following: X including any one or any two or more of Ni, Co, Pd, Au and Pt, the content of X being 0.03 to 0.32% by mass in total; any one or any two or more of Mg, P and Ge in a content of 0.0001 to 0.108% by mass in total; and the balance composed of Sn and inevitable impurities.

The lead-free solder bump 10 may include any one or two or more of the above-described Ag, Cu and Bi. In this case, the lead-free solder bump 10 may have a composition including the following: X including any one or any two or more of Ni, Co, Pd, Au and Pt, the content of X being 0.03 to 0.32% by mass in total; any one or two or more of Ag, Cu and Bi in a content of 0.03 to 0.32% by mass in total; any one or any two or more of Mg, P and Ge in a content of 0.0001 to 0.108% by mass in total; and the balance composed of Sn and inevitable impurities.

In the lead-free solder bump 10 having one of the above-described various compositions in the lead-free solder bump joining structure 1 the present invention, the average thickness of the intermetallic compound layer 11 (12), which is formed in the joining interface with the Cu electrode 4 (7), is preferably 0.4 [μm] or more and 1.2 [μm] or less. When the average thickness of the intermetallic compound layer 11 (12) is less than 0.4 [μm], the intermetallic compound layer 11 (12) disappears at an early stage, which is not preferable. When the average thickness of the intermetallic compound layer 11 (12) exceeds 1.2 [μm], the concentration of X which forms a substitutional solid solution by replacing Cu is low, and the effect of suppressing the migration of Cu in the intermetallic compound layer 11 (12) is not sufficient.

In order to obtain the average thickness of the intermetallic compound layer 11 (12), for example, there may be used an image processing software capable of specifying and extracting the region of the intermetallic compound layer 11(12) at a cross-sectional position, or other various methods. For example, the cross-sectional region of the intermetallic compound layer 11 (12) is visually extracted on the basis of the cross-sectional image of, for example, an optical microscope photograph or a SEM photograph of the intermetallic compound layer 11 (12), and the area of the extracted region is calculated by using an image analysis software (for example, Image J). The average thickness is calculated from the total width of the intermetallic compound layer 11 (12), which extends along the joining interface with the Cu electrode 4 (7) in the cross-sectional image, and the area of the intermetallic compound layer 11 (12).

In the lead-free solder bump joining structure of the present invention, the content of Fe in the lead-free solder bump 10 is preferably equal to or less than the detection limit of ICP (Inductively Coupled Plasma) analysis. Setting the content of Fe in the lead-free solder bump 10 to be equal to or less than the detection limit of the ICP analysis prevents the increase of the disconnection failure caused by the synergistic effect of the electromigration phenomenon and the thermomigration phenomenon. Here, the ICP analysis refers to the ICP emission spectroscopic analysis or the ICP mass analysis, and “equal to or less than the detection limit” means equal to or less than the detection limit in the ICP emission spectroscopic analysis or the ICP mass analysis.

The above-described inevitable impurities refer to the impurity elements inevitably mixed into the materials during the production process including refining and dissolution. For example, in the case of Zn, Al and Cd, the inevitable impurities refer to 30 ppm by mass or less of Zn, Al and Cd. Examples of the inevitable impurities include Sab and As in addition to the above.

The method for identifying the composition of the lead-free solder bump 10 is not particularly limited; however, because of proven records and high accuracy, for example, the following methods are preferable: energy dispersive X-ray spectrometry (EDS), electron probe micro analysis (EPMA), Auger electron spectroscopy (AES), secondary ion-microprobe mass spectrometry (SIMS), inductively coupled plasma (ICP) analysis, glow discharge mass spectrometry (GD-MASS), and X-ray fluorescence spectrometry (XRF).

In the case where the lead-free solder bump joining structure 1 of the present invention is used in the mounting in a semiconductor memory, or used in the mounting in the vicinity of a semiconductor memory, and the lead-free solder bump 10 emits α-rays, the α-rays may affect the semiconductor memory and may delete the data. In consideration of the effect of α-rays on the semiconductor memory in the lead-free solder bump joining structure 1 of the present invention, it is desirable form the lead-free solder bump 10 from a so-called low α-ray dose lead-free solder alloy having an α-ray dose smaller than usual such that the α-ray dose of the lead-free solder bump 10 is 1 [cph/cm²] or less. The lead-free solder bump 10 having such a low α-ray dose is achieved by producing the lead-free solder bump having the above-described composition with the use of a raw material that is high-purity Sn having a purity of 99,99% or more prepared by removing the impurities from which the α-rays are generated.

When the above-described element (s) X (namely, Ni, Co, Pd, Au, or Pt) is added to the lead-free solder alloy before being formed into the lead-free solder bump 10, the added element(s) X in the lead-free solder alloy is bonded to Sn in the lead-free solder alloy, to form a Sn—X type intermetallic compound. Specifically, when the lead-free solder bump 10 is formed by mounting the lead-free solder alloy on the Cu electrode 4, the Sn—X type intermetallic compound in the lead-free solder bump 10 is decomposed, and the element(s) X generated by this decomposition reacts with the Cu of the Cu electrode 4, which is in contact with the lead-free solder bump 10, or the Sn in the lead-free solder bump 10, and thus (Cu, X) ₆Sn₅ is formed.

However, in a case where the element(s) X is merely added to the raw material in the production of a lead-free solder alloy, it is difficult to effectively form (Cu, X) ₆Sn₅ in the joining interface with the Cu electrode 4 when the lead-free solder bump 10 is formed on the Cu electrode 4. In a case where the element(s) X is merely added to the raw material of the lead-free solder alloy in the course of the production process of the lead-free solder alloy, which is to be the lead-free solder bump 10, the Sn—X type intermetallic compound is coarsened in the lead-free solder alloy, and a small number of coarse Sn—X type intermetallic compounds are formed. When the number of the Sn—X type intermetallic compounds is small as described above, the number of the Sn—X type intermetallic compounds in the lead-free solder bump 10 in contact with the Cu electrode 4 is also decreased at the time of forming the lead-free solder bump 10 on the Cu electrode 4. Thus the chance of the reaction of the element (s) X in the lead-free solder bump 10 with the Cu in the Cu electrode 4 is reduced, thus it is difficult to form the intermetallic compound layer 11 composed of (Cu, X) ₆Sn₅ with a uniform and necessary thickness in the joining interface with the Cu electrode 4. In some cases, there is a high possibility that there is partially formed an intermetallic compound layer composed of Cu₆Sn₅ other than (Cu, X) ₆Sn₅.

Accordingly, in the production of the lead-free solder alloy, it is desirable to heat a solder master alloy which includes the element(s) X in accordance with the predetermined concentration, to a temperature equal to or higher than the melting point of the Sn—X type intermetallic compound, so as to melt the Sn—X type intermetallic compound produced in the lead-free solder alloy, and then rapidly cool the solder material. Thus, in the present invention, when the lead-free solder bump 10 is formed on the Cu electrode 4, the intermetallic compound layer 11 composed of (Cu, X) ₆Sn₅ is formed optimally in the joining interface with the Cu electrode 4.

Specifically, through the production steps described above, a large number of the fine Sn—X type intermetallic compounds are formed in the lead-free solder alloy. Consequently when the lead-free solder bump 10 is formed on the Cu electrode 4, the lead-free solder bump 10 contains a sufficient number of the Sn—X type intermetallic compounds in contact with the interface of the Cu electrode 4. The X in the lead-free solder bump 10 reacts reliably with the Cu of the Cu electrode 4, and thus intermetallic compound layer 11 composed of (Cu, X) ₆Sn₅ is formed with the uniform and necessary thickness in the joining interface with the Cu electrode 4.

Here, the above-described heating temperature in the course of the production process of the lead-free solder alloy, which is to be the lead-free solder bump 10, is determined by the melting point of the Sn—X type intermetallic compound. For example, as shown in equilibrium diagrams, the melting point of the Au—Sn type intermetallic compound is 532° C. at the highest, the melting point of the Co—Sn type intermetallic compound is 1170° C. at the highest, the melting point of the Ni—Sn type intermetallic compound is 1300° C. at the highest, the melting point of the Pd—Sn type intermetallic compound is 1326° C. at the highest and the melting point of the Pt—Sn type intermetallic compound is 1365° C. at the highest. Accordingly, when the element X is a single element selected from Ni, Co, Pd, Au and Pt, the solder master alloy is heated preferably at a temperature equal to or higher than the above-described corresponding highest melting point; when two or more of Ni, Co, Pd, Au and Pt are included as X, the solder master alloy is heated preferably at a temperature equal to or higher than the highest temperature of the above-described corresponding highest melting points.

In the above-described lead-free solder bump joining structure 1 of the present invention, the X in a content of 0.03 to 0.32% by mass in total including any one or any two or more of Ni, Co, Pd, Au and Pt is included in the lead-free solder bump 10 joining the Cu electrode 4 of the first electronic member 2 and the Cu electrode 7 of the second electronic member 5. The intermetallic compound layers 11 and 12, each composed of (Cu, X) ₆Sn₅ including X, are formed in the joining interfaces with the Cu electrodes 4 and 7, respectively, in the lead-free solder bump 10.

In the lead-free solder bump joining structure 1, even when an electric current having an electric current density of 0.7×10³ [A/cm²] or more flows continuously between the first electronic member 2 and the second electronic member 5 through the lead-free solder bump 10, the diffusion of Cu from the intermetallic compound layers 11 and 12, which are formed in the joining interfaces with the Cu electrodes 4 and 7 in the lead-free solder bump 10, is suppressed. Correspondingly, the disappearance of the intermetallic compound layers and the disappearance of the Cu electrodes, which have been caused by the diffusion of Cu, are suppressed.

In the lead-free solder bump joining structure 1, the diffusion of Cu from the intermetallic compound layers 11 and 12, which are formed in the joining interfaces with the Cu electrodes 4 and 7 in the lead-free solder bump 10, is suppressed and the intermetallic compound layers 11 and 12 are not likely to disappear. Correspondingly, with the use of the intermetallic compound layers 11 and 12, Cu is not likely to diffuse from the Cu electrodes 4 and 7 into the lead-free solder bump 10. Even when an electric current flows continuously between the first electronic member 2 and the second electronic member 5 through the lead-free solder bump 10, the occurrences of the electromigration phenomenon and the thermomigration phenomenon are suppressed, and thus, the disconnection failure caused by the synergistic effect of the electromigration phenomenon and the thermomigration phenomenon is suppressed.

### EXAMPLES

Hereinafter, the effects of the present invention are described more specifically with reference to Examples (shown as “Ex.” in tables below). First, a lead-free solder alloy (Sn-1.2Ag-0.5Cu-0.03Ni) containing Ni: 0.03% by mass as X, Ag: 1.2% by mass, and Cu: 0.5% by mass, and the balance composed of Sn and inevitable impurities was used to form a lead-free solder bump 10 between the Cu electrodes 4 and 7. Thus the lead-free solder bump joining structure 1 according to one of Examples was prepared. Then, the states of the intermetallic compound layers 11 and 12 and the Cu electrodes 4 and 7 were examined when a predetermined electric current was continuously supplied between the Cu electrodes 4 and 7 of the lead-free solder bump joining structure 1.

In this case, a wafer level package (WLP) was used as the first electronic member 2, and a substrate composed of a ET resin (bismaleimide-triazine resin) was used as the second electronic member 5. First, a solder master alloy, which includes various elements in accordance with the predetermined concentrations, was heated to a temperature equal to or higher than the melting point of the Ni—Sn type intermetallic compound, thus the Ni—Sn type intermetallic compound produced in the lead-free solder alloy was melted. Then the solder raw material was rapidly cooled, and thus, a lead-free solder alloy including Sn-1.2Ag-0.5Cu—Ni was prepared.

Next, the lead-free solder alloy including Sn-1.2Ag-0.5Cu—Ni was used to form the lead-free solder bump 10 on the Cu electrode 4 of the first electronic member 2 (WLP). Actually, a WLP provided with a columnar Cu electrode 4 having the diameter of 200 [μm] was used as the first electronic member 2. The Cu electrode 4 was coated with a flux, then a lead-free solder ball, which was prepared by shaping the above-described lead-free solder alloy into a ball shape, was directly placed on the Cu electrode 4, preheated at 150[° C.] for 70 seconds, and then reflowed at 260[°C.] for 40 seconds to form a lead-free solder bump 10 on the surface of the Cu electrode 4.

Next, the first electronic member 2 joined with the lead-free solder bump 10 was reversed upside down; the lead-free solder bump 10 was directly placed on the flux-coated Cu electrode 7 of the second electronic member 5 (substrate), preheated at 150[° C.] for 70 seconds, and then reflowed at 260[° C.] for 40 seconds to join the lead-free solder bump 10 on the surface of the Cu electrode 7; thus, a lead-free solder bump joining structure 1 according to one of Examples was prepared.

Lead-free solder bump joining structures according to Comparative Examples (shown as C. Ex. in tables below) are prepared. The composition of the lead-free solder bump was altered from the composition of the lead-free solder bump joining structure 1 according to Examples. The lead-free solder bump joining structure was prepared by using a conventional lead-free solder alloy to which X was not added. In this case, in Comparative Examples, a lead-free solder alloy (Sn-3Ag-0.5Cu) including Ag: 3.0% by mass, Cu: 0.5% by mass, and the balance composed of Sn and inevitable impurities was used without adding X, to prepare a lead-free solder bump joining structure, which joins the Cu electrodes, under the same conditions as described above.

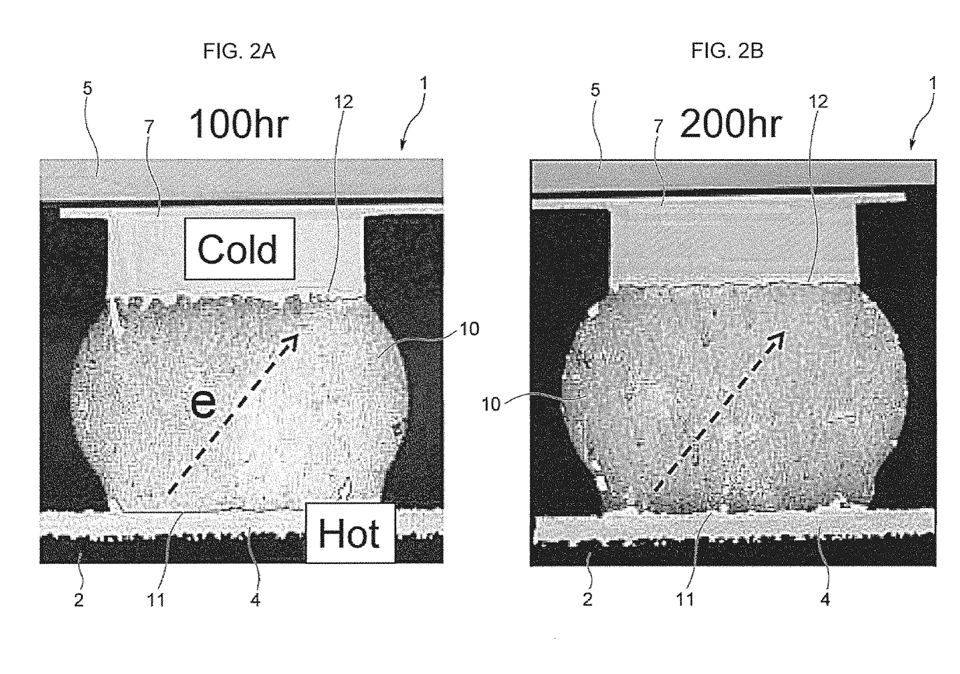

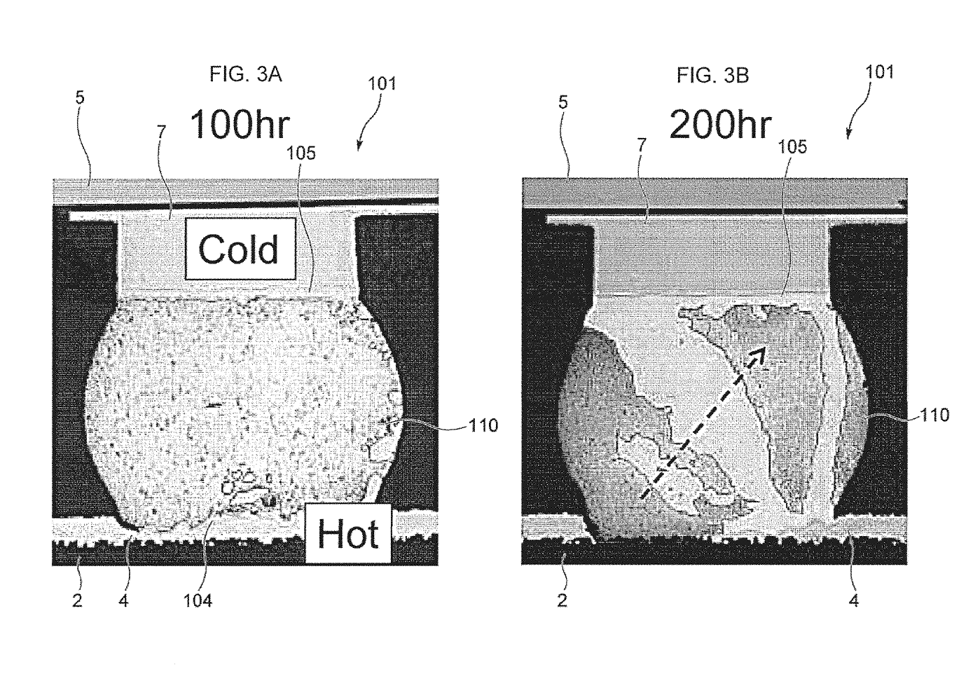

Next, in each of the Examples and the Comparative Examples, an electric current of 2.0 [A] (electric current density: 6370 [A/cm²]) was applied from the upper Cu, electrode to the lower Cu electrode through the lead-free solder bump. Under the condition that the atmospheric temperature was 66[° C.], the states of the cross-section of the lead-free solder bump joining structure after 100 hours and 200 hours were examined using the metallurgical microscope photographs. FIG. 2A is a metallurgical microscope photograph showing the state of the lead-free solder bump joining structure 1 including Ni as X, after 100 hours according to one of Examples. FIG. 2B is a metallurgical microscope photograph showing the state of the lead-free solder bump joining structure 1 after 200 hours according to the same Example as that shown in FIG. 2A. FIG. 3A is a metallurgical microscope photograph showing the state of the lead-free solder bump joining structure 101 without after 100 hours according to one of Comparative Examples. FIG. 3B is a metallurgical microscope photograph showing the state of the lead-free solder bump joining structure 101 after 200 hours according to the same Comparative Example as that shown in FIG. 3A.

After an elapsed time of 100 hours, in the lead-free solder bump joining structure 101 without X according to one of Comparative Examples shown in FIG. 3A, the diffusion of Cu was not verified in the intermetallic compound layer 105 formed on the upper Cu electrode 7 being lower in temperature. However, on the lower Cu electrode 4 being higher in temperature, was verified that a portion of the intermetallic compound layer 104 started to spread into the lead-free solder bump 110, and the diffusion of Cu in the intermetallic compound layer 104 started. As shown in FIG. 3B, in the lead-free solder bump joining structures 101 of the one of Comparative Examples, it was verified that after an elapsed time of 200 hours, the intermetallic compound layer 104, which was present at the interface with the lower Cu electrode being higher in temperature, disappeared completely, and also the Cu electrode 4 was replaced with the lead-free solder bump 10.

According to the results of the verification of the present inventors, the disappearance of the Cu electrode 4 progresses very fast after the disappearance of the intermetallic compound layer 104 on the Cu electrode 4 on the higher temperature side of the lead-free solder bump 110, as compared with the period of time until the intermetallic compound layer 104 disappeared.

On the contrary, in the lead-free solder bump joining structure 1 of the one of Examples including Ni as X, it was verified that as shown in FIG. 2A, the intermetallic compound layer 11 having a predetermined thickness was continuously formed also at the interface with the lower Cu electrode 4 being higher in temperature in the lead-free solder bump 10, even after an elapsed time of 100 hours. Moreover, in the lead-free solder bump joining structure 1 of the one of Examples, it was verified that as shown in FIG. 2B, the intermetallic compound layer 11 having a predetermined thickness was formed along the interface with the lower Cu electrode 4 being higher in temperature in the lead-free solder bump 10, even after an elapsed time of 200 hours. Thus, it was verified that the intermetallic compound layer 11 continued to remain without disappearing.

Thus, it was verified that in the lead-free solder bump joining structure 1, the diffusion of Cu from the intermetallic compound layers 11 and 12, which are formed in the joining interfaces with the Cu electrodes 4 and 7 in the lead-free solder bump 10, was suppressed by adding Ni in the lead-free solder bump 10; and correspondingly, the intermetallic compound layers 11 and 12 continued to remain without disappearing. With the use of the intermetallic compound layers 11 and 12, the diffusion of Cu from the Cu electrodes 4 and 7 into the lead-free solder bump 10 is unlikely to occur, and the disconnection failure caused by the synergistic effect of the electromigration phenomenon and the thermomigration phenomenon was suppressed.

Next, the composition of the lead-free solder alloy, which is to be the lead-free solder bump, was varied, and each lead-free solder bump was formed between the Cu electrode 4 of the first electronic member 2 and the Cu electrode 7 of the second electronic member 5 by using the different lead-free solder alloy. Thus a plurality of types of lead-free solder bump joining structures are formed each joining the Cu electrodes 4 and 7 through the lead-free solder bump. Similar to the one of Examples (FIG. 2) and the one of Comparative Examples (FIG. 3), a wafer level package (WLP) cut out from a Si chip was used as the first electronic member 2 and a substrate composed of a BT resin was used as the second electronic member 5.

In each of Examples 1 to 29 and Comparative Examples 1 to 10 shown in Table 1 presented below, in order to prepare the lead-free solder alloy, the solder master alloy including the element(s) X (namely, Ni, Co, Pd, Au, or Pt) corresponding to the predetermined concentration(s) was prepared; then, the solder master alloy was heated to a temperature equal to or higher than the melting point, of the Sn—X type intermetallic compound. Thereby the Sn—X type intermetallic compound produced in the lead-free solder alloy was melted, and then the solder raw material was rapidly cooled to prepare a lead-free solder bump alloy. Then, with the use of the lead-free solder alloy having the components shown in Table 1, the lead-free solder hump joining structure joining the Cu electrodes through a lead-free solder bump was prepared under the same conditions as in foregoing Examples or Comparative Examples.

TABLE 1

| | | | | | | | EM Property, |
|---|---|---|---|---|---|---|---|
| | Sn | Ni | Co | Pd | Au | Pt | TM Property |
| Ex. 1 | Balance | 0.03 | | | | | ◯◯ |
| Ex. 2 | Balance | 0.05 | | | | | ◯◯ |
| Ex. 3 | Balance | 0.08 | | | | | ◯◯ |
| Ex. 4 | Balance | 0.10 | | | | | ◯ |
| Ex. 5 | Balance | 0.15 | | | | | ◯ |
| Ex. 6 | Balance | | 0.10 | | | | ◯◯◯ |
| Ex. 7 | Balance | | 0.15 | | | | ◯◯◯ |
| Ex. 8 | Balance | | 0.20 | | | | ◯◯◯ |
| Ex. 9 | Balance | | | 0.10 | | | ◯◯◯◯ |
| Ex. 10 | Balance | | | 0.15 | | | ◯◯◯◯ |
| Ex. 11 | Balance | | | 0.20 | | | ◯◯◯◯ |
| Ex. 12 | Balance | | | | 0.15 | | ◯◯◯ |
| Ex. 13 | Balance | | | | 0.20 | | ◯◯◯ |
| Ex. 14 | Balance | | | | 0.25 | | ◯◯◯ |
| Ex. 15 | Balance | | | | | 0.15 | ◯◯◯ |
| Ex. 16 | Balance | | | | | 0.20 | ◯◯◯ |
| Ex. 17 | Balance | | | | | 0.25 | ◯◯◯ |
| Ex. 18 | Balance | 0.04 | 0.10 | | | | ◯◯◯◯ |
| Ex. 19 | Balance | 0.05 | 0.15 | | | | ◯◯◯◯ |
| Ex. 20 | Balance | 0.07 | 0.20 | | | | ◯◯◯◯ |
| Ex. 21 | Balance | 0.04 | | 0.10 | | | ◯◯◯◯◯ |
| Ex. 22 | Balance | 0.05 | | 0.15 | | | ◯◯◯◯◯ |
| Ex. 23 | Balance | 0.07 | | 0.20 | | | ◯◯◯◯◯ |
| Ex. 24 | Balance | 0.04 | | | 0.15 | | ◯◯◯◯ |
| Ex. 25 | Balance | 0.05 | | | 0.20 | | ◯◯◯◯ |
| Ex. 26 | Balance | 0.07 | | | 0.25 | | ◯◯◯◯ |
| Ex. 27 | Balance | 0.04 | | | | 0.15 | ◯◯◯◯ |
| Ex. 28 | Balance | 0.05 | | | | 0.20 | ◯◯◯◯ |
| Ex. 29 | Balance | 0.07 | | | | 0.25 | ◯◯◯◯ |
| C. Ex. 1 | Balance | 0.01 | | | | | X |
| C. Ex. 2 | Balance | | 0.01 | | | | X |
| C. Ex. 3 | Balance | | | 0.01 | | | X |
| C. Ex. 4 | Balance | | | | 0.01 | | X |
| C. Ex. 5 | Balance | | | | | 0.01 | X |
| C. Ex. 6 | Balance | 0.35 | | | | | X |
| C. Ex. 7 | Balance | | 0.35 | | | | X |
| C. Ex. 8 | Balance | | | 0.35 | | | X |
| C. Ex. 9 | Balance | | | | 0.35 | | X |
| C. Ex. 10 | Balance | | | | | 0.35 | X |

Verification tests for the evaluation of the EM property and the TM property (in the table, indicated as “EM property, TM property”) were performed for these lead-free solder bump joining structures, and the results are shown in Table 1. The EM property and the TM property were evaluated on the basis of the operating life until the disconnection failure occurred. The EM property and the TM property were evaluated as follows: the case where the disconnection failure occurred within a range of 500 hours or more and less than 700 hours was marked with one circle. The case where the disconnection failure occurred within a range of 700 hours or more and less than 900 hours was marked with two circles. The case where the disconnection failure occurred within a range of 900 hours or more and less than 1100 hours was marked with three circles. The case where the disconnection failure occurred within a range of 1100 hours or more and less than 1300 hours was marked with four circles. The case where the disconnection failure occurred within a range of 1300 hours or more was marked with five circles. The case where the disconnection failure occurred within a range of less than 500 hours was marked with a cross mark X.

As shown in Table 1, in each of the lead-free solder bump joining structures, which include X, of Examples 1 to 29, the EM property and the TM property were evaluated as the single circle or higher, and the exterior appearance was also evaluated as the single circle. In this case, in each of Examples 6 to 17 including any one of Co, Pd, Au and Pt as X, the evaluation of the EM property and the TM property was better than the evaluations in Examples 1 to 5 including Ni as X. In particular, the evaluation of the EM property and the TM property in each of Examples 8 to 11 including one element Pd as X was the best.

In each of Examples 18 to 29 including Ni and any one of Co, Pd, Au and Pt as X, the evaluation of the EM property and the TM property was better than the evaluations in Examples 1 to 17 including any one of Ni, Co, Pd, Au and Pt as X. It was verified that occurrence of the disconnection failure was further suppressed.

On the other hand, in Comparative Examples 1 to 5, in each of which the content of X is 0.01% by mass, and Comparative Examples 6 to 10, in each of which the content of X is 0.35% by mass, the EM property and the TM property were evaluated as a cross mark (X), and no satisfactory results were obtained. Accordingly, it has been verified that in order to improve the evaluation of the EM property and the TM property, the content of X is preferably 0.03% by mass or more and less than 0.32% by mass.

Next, as shown in Table 2 presented below, with the use of lead-free solder alloys including any one or more of Ag, Cu and Bi in addition to X, lead-free solder bump joining structures joining the Cu electrodes through the lead-free solder bump were prepared under the same conditions as in foregoing Examples 1 to 29 and Comparative Examples 1 to 10. Here, in addition to the EM property and the TM property, the TCT property was also evaluated.

TABLE 2

| | | | | | | | | | | EM | |
|---|---|---|---|---|---|---|---|---|---|---|---|
| | | | | | | | | | | Property, | |
| | | | | | | | | | | TM | TCT |
| | Sn | Ni | Co | Pd | Au | Pt | Ag | Cu | Bi | Property | Property |
| Ex. | Balance | 0.03 | | | | | 0.5 | 0.3 | | ∘∘ | ∘ |
| 30 | | | | | | | | | | | |
| Ex. | Balance | 0.05 | | | | | 3.0 | 0.5 | | ∘∘ | ∘∘ |
| 31 | | | | | | | | | | | |
| Ex. | Balance | 0.08 | | | | | 4.0 | 1.2 | | ∘∘ | ∘∘ |
| 32 | | | | | | | | | | | |
| Ex. | Balance | | 0.10 | | | | 0.5 | 0.5 | | ∘∘∘ | ∘ |
| 33 | | | | | | | | | | | |
| Ex. | Balance | | 0.15 | | | | 3.0 | 1.2 | | ∘∘∘ | ∘∘ |
| 34 | | | | | | | | | | | |
| Ex. | Balance | | 0.20 | | | | 4.0 | 0.3 | | ∘∘∘ | ∘∘ |
| 35 | | | | | | | | | | | |
| Ex. | Balance | | | 0.10 | | | 0.5 | 1.2 | | ∘∘∘∘ | ∘ |
| 36 | | | | | | | | | | | |
| Ex. | Balance | | | 0.15 | | | 3.0 | 0.3 | | ∘∘∘∘ | ∘∘ |
| 37 | | | | | | | | | | | |
| Ex. | Balance | | | 0.20 | | | 4.0 | 0.5 | | ∘∘∘∘ | ∘∘ |
| 38 | | | | | | | | | | | |
| Ex. | Balance | | | | 0.15 | | 0.5 | 0.3 | | ∘∘∘ | ∘ |
| 39 | | | | | | | | | | | |
| Ex. | Balance | | | | 0.20 | | 3.0 | 0.5 | | ∘∘∘ | ∘∘ |
| 40 | | | | | | | | | | | |
| Ex. | Balance | | | | 0.25 | | 4.0 | 1.2 | | ∘∘∘ | ∘∘ |
| 41 | | | | | | | | | | | |
| Ex. | Balance | | | | | 0.15 | 0.5 | 0.5 | | ∘∘∘ | ∘ |
| 42 | | | | | | | | | | | |
| Ex. | Balance | | | | | 0.20 | 3.0 | 1.2 | | ∘∘∘ | ∘∘ |
| 43 | | | | | | | | | | | |
| Ex. | Balance | | | | | 0.25 | 4.0 | 0.3 | | ∘∘∘ | ∘∘ |
| 44 | | | | | | | | | | | |
| Ex. | Balance | 0.03 | | | | | | | 0.1 | ∘ | ∘ |
| 45 | | | | | | | | | | | |
| Ex. | Balance | 0.05 | | | | | | | 1.0 | ∘ | ∘∘ |
| 46 | | | | | | | | | | | |
| Ex. | Balance | 0.08 | | | | | | | 3.0 | ∘ | ∘∘∘ |
| 47 | | | | | | | | | | | |
| Ex. | Balance | | 0.10 | | | | | | 0.1 | ∘∘ | ∘ |
| 48 | | | | | | | | | | | |
| Ex. | Balance | | 0.15 | | | | | | 1.0 | ∘∘ | ∘∘ |
| 49 | | | | | | | | | | | |
| Ex. | Balance | | 0.20 | | | | | | 3.0 | ∘∘ | ∘∘∘ |
| 50 | | | | | | | | | | | |
| Ex. | Balance | | | 0.10 | | | | | 0.1 | ∘∘∘ | ∘ |
| 51 | | | | | | | | | | | |
| Ex. | Balance | | | 0.15 | | | | | 1.0 | ∘∘∘ | ∘∘ |
| 52 | | | | | | | | | | | |
| Ex. | Balance | | | 0.20 | | | | | 3.0 | ∘∘∘ | ∘∘∘ |
| 53 | | | | | | | | | | | |
| Ex. | Balance | | | | 0.15 | | | | 0.1 | ∘∘ | ∘ |
| 54 | | | | | | | | | | | |
| Ex. | Balance | | | | 0.20 | | | | 1.0 | ∘∘ | ∘∘ |
| 55 | | | | | | | | | | | |
| Ex. | Balance | | | | 0.25 | | | | 3.0 | ∘∘ | ∘∘∘ |
| 56 | | | | | | | | | | | |
| Ex. | Balance | | | | | 0.15 | | | 0.1 | ∘∘ | ∘ |
| 57 | | | | | | | | | | | |
| Ex. | Balance | | | | | 0.20 | | | 1.0 | ∘∘ | ∘∘ |
| 58 | | | | | | | | | | | |
| Ex. | Balance | | | | | 0.25 | | | 3.0 | ∘∘ | ∘∘∘ |
| 59 | | | | | | | | | | | |
| Ex. | Balance | 0.04 | 0.10 | | | | 3.0 | | 1.0 | ∘∘∘∘ | ∘∘∘∘ |
| 60 | | | | | | | | | | | |
| Ex. | Balance | 0.05 | 0.15 | | | | 1.0 | 0.5 | 0.1 | ∘∘∘∘ | ∘∘ |
| 61 | | | | | | | | | | | |
| Ex. | Balance | 0.07 | 0.20 | | | | 4.0 | | 3.0 | ∘∘∘∘ | ∘∘∘∘∘ |
| 62 | | | | | | | | | | | |
| Ex. | Balance | 0.04 | | 0.10 | | | 3.0 | | 1.0 | ∘∘∘∘∘ | ∘∘∘∘ |
| 63 | | | | | | | | | | | |
| Ex. | Balance | 0.05 | | 0.15 | | | 1.0 | 0.5 | 0.1 | ∘∘∘∘∘ | ∘∘ |
| 64 | | | | | | | | | | | |
| Ex. | Balance | 0.07 | | 0.20 | | | 4.0 | | 3.0 | ∘∘∘∘∘ | ∘∘∘∘∘ |
| 65 | | | | | | | | | | | |
| Ex. | Balance | 0.04 | | | 0.15 | | 3.0 | | 1.0 | ∘∘∘∘ | ∘∘∘∘ |
| 66 | | | | | | | | | | | |
| Ex. | Balance | 0.05 | | | 0.20 | | 1.0 | 0.5 | 0.1 | ∘∘∘∘ | ∘∘ |
| 67 | | | | | | | | | | | |
| Ex. | Balance | 0.07 | | | 0.25 | | 4.0 | | 3.0 | ∘∘∘∘ | ∘∘∘∘∘ |
| 68 | | | | | | | | | | | |
| Ex. | Balance | 0.04 | | | | 0.15 | 3.0 | | 1.0 | ∘∘∘∘ | ∘∘∘∘ |
| 69 | | | | | | | | | | | |
| Ex. | Balance | 0.05 | | | | 0.20 | 1.0 | 0.5 | 0.1 | ∘∘∘∘ | ∘∘ |
| 70 | | | | | | | | | | | |
| Ex. | Balance | 0.07 | | | | 0.25 | 4.0 | | 3.0 | ∘∘∘∘ | ∘∘∘∘∘ |
| 71 | | | | | | | | | | | |

The TCT test performing the evaluation of the TCT property was performed as follows: a series of the step of maintaining a specimen at −40[° C.] for 30 minutes and step of then maintaining the specimen at 125[°C.] for 30 minutes was defined as one cycle, and this one cycle was continuously repeated for a predetermined number of cycles. Every time the one cycle was performed 25 times, the specimen (a lead-free solder bump joining structure) was taken out from the TOT test apparatus, and there was performed a conduction test measuring the electric resistance value of the lead-free solder bump joining structure joining the first electronic member and the second electronic member through the lead-free solder bump. In the conduction test, when the electric resistance value between the first electronic member and the second electronic member exceeded the initial value of 2 [Ω], which was obtained before the TCT test, it was regarded that a failure occurred. The results thus obtained are shown in the column under the heading of “TCT property” in Table 2.

In the column under the heading of “TOT property” in Table 2, the case where the number of the cycles at which the failure occurred for the first time was more than 200 and 400 or less was marked with one circle, which indicates a practically usable level. The case where the number of the cycles at which the failure occurred for the first time was more than 400 and 600 or less was marked with two circles, which means satisfactory. The case where the number of the cycles at which the failure occurred for the first time was more than 600 and 800 or less was marked with three circles. The case where the number of the cycles at which the failure occurred for the first time was more than 800 and 1000 or less was marked with four circles. The case where the number of the cycles at which the failure occurred for the first time was more than 1000 was marked with five circles.

When Examples 45 to 59 including X and Bi in table 2 were compared with Examples 1 to 17 including X but not including Bi in Table 1, most of evaluations of the EM property and the TM property in Examples 1 to 17 not including Bi were better than those of Examples 45 to 47 including Bi. Accordingly, it was verified that when satisfactory EM property and satisfactory TM property are preferentially demanded, the inclusion of Bi is not desirable.

It was verified from Table 2 that in Examples 60, 62, 63, 65, 66, 68, 69 and 71 including Ni and any one of Co, Pd, Au and Pt as X, and two elements, namely, Ag and Bi, the evaluations of the EM property and the TM property, and the TOT property had good results.

Next, as shown in Table 3 presented below, lead-free solder bump joining structures joining the Cu electrodes through a lead-free solder bump were prepar by using lead-free solder alloys including X, at least one or more of Ag, Cu and Bi, and at least one or more of Mg, P and Ge, under the same conditions as in forgoing Examples 1 to 71 and forgoing Comparative Examples 1 to 10. Here, in addition to the evaluation of the EM property and the TM property, the evaluation of temporal variation prevention effect, which is an effect of preventing temporal changes, was also performed.

TABLE 3

| | | | | | | | | | | | | | EM | Temporal |
|---|---|---|---|---|---|---|---|---|---|---|---|---|---|---|
| | | | | | | | | | | | | | Property, | variation |
| | | | | | | | | | | | | | TM | prevention |
| | Sn | Ni | Co | Pd | Au | Pt | Ag | Cu | Bi | Mg | P | Ge | Property | effect |
| Ex. | Balance | 0.03 | | | | | 0.5 | 0.3 | | 0.0001 | | | ∘∘ | ∘ |
| 72 | | | | | | | | | | | | | | |
| Ex. | Balance | 0.05 | | | | | 3.0 | 0.5 | | 0.0010 | | | ∘∘ | ∘∘ |
| 73 | | | | | | | | | | | | | | |
| Ex. | Balance | 0.08 | | | | | 4.0 | 1.2 | | 0.0040 | | | ∘∘ | ∘∘ |
| 74 | | | | | | | | | | | | | | |
| Ex. | Balance | | 0.10 | | | | 0.5 | 0.5 | | | 0.0001 | | ∘∘∘ | ∘ |
| 75 | | | | | | | | | | | | | | |
| Ex. | Balance | | 0.15 | | | | 3.0 | 1.2 | | | 0.0100 | | ∘∘∘ | ∘∘ |
| 76 | | | | | | | | | | | | | | |
| Ex. | Balance | | 0.20 | | | | 4.0 | 0.3 | | | 0.1000 | | ∘∘∘ | ∘∘ |
| 77 | | | | | | | | | | | | | | |
| Ex. | Balance | | | 0.10 | | | 0.5 | 1.2 | | | | 0.0001 | ∘∘∘∘ | ∘ |
| 78 | | | | | | | | | | | | | | |
| Ex. | Balance | | | 0.15 | | | 3.0 | 0.3 | | | | 0.0010 | ∘∘∘∘ | ∘∘ |
| 79 | | | | | | | | | | | | | | |
| Ex. | Balance | | | 0.20 | | | 4.0 | 0.5 | | | | 0.0040 | ∘∘∘∘ | ∘∘ |
| 80 | | | | | | | | | | | | | | |
| Ex. | Balance | | | | 0.15 | | 0.5 | 0.3 | | 0.0001 | | | ∘∘∘ | ∘ |
| 81 | | | | | | | | | | | | | | |
| Ex. | Balance | | | | 0.20 | | 3.0 | 0.5 | | 0.0010 | | | ∘∘∘ | ∘∘ |
| 82 | | | | | | | | | | | | | | |
| Ex. | Balance | | | | 0.25 | | 4.0 | 1.2 | | 0.0040 | | | ∘∘∘ | ∘∘ |
| 83 | | | | | | | | | | | | | | |
| Ex. | Balance | | | | | 0.15 | 0.5 | 0.5 | | | 0.0001 | | ∘∘∘ | ∘ |
| 84 | | | | | | | | | | | | | | |
| Ex. | Balance | | | | | 0.20 | 3.0 | 1.2 | | | 0.0100 | | ∘∘∘ | ∘∘ |
| 85 | | | | | | | | | | | | | | |
| Ex. | Balance | | | | | 0.25 | 4.0 | 0.3 | | | 0.1000 | | ∘∘∘ | ∘∘ |
| 86 | | | | | | | | | | | | | | |
| Ex. | Balance | 0.03 | | | | | | | 0.1 | | | 0.0001 | ∘ | ∘ |
| 87 | | | | | | | | | | | | | | |
| Ex. | Balance | 0.05 | | | | | | | 1.0 | | | 0.0010 | ∘ | ∘∘ |
| 88 | | | | | | | | | | | | | | |
| Ex. | Balance | 0.08 | | | | | | | 3.0 | | | 0.0040 | ∘ | ∘∘ |
| 89 | | | | | | | | | | | | | | |
| Ex. | Balance | | 0.10 | | | | | | 0.1 | 0.0001 | | | ∘∘ | ∘ |
| 90 | | | | | | | | | | | | | | |
| Ex. | Balance | | 0.15 | | | | | | 1.0 | 0.0010 | | | ∘∘ | ∘∘ |
| 91 | | | | | | | | | | | | | | |
| Ex. | Balance | | 0.20 | | | | | | 3.0 | 0.0040 | | | ∘∘ | ∘∘ |
| 92 | | | | | | | | | | | | | | |
| Ex. | Balance | | | 0.10 | | | | | 0.1 | | 0.0001 | | ∘∘∘ | ∘ |
| 93 | | | | | | | | | | | | | | |
| Ex. | Balance | | | 0.15 | | | | | 1.0 | | 0.0100 | | ∘∘∘ | ∘∘ |
| 94 | | | | | | | | | | | | | | |
| Ex. | Balance | | | 0.20 | | | | | 3.0 | | 0.1000 | | ∘∘∘ | ∘∘ |
| 95 | | | | | | | | | | | | | | |
| Ex. | Balance | | | | 0.15 | | | | 0.1 | | | 0.0001 | ∘∘ | ∘ |
| 96 | | | | | | | | | | | | | | |
| Ex. | Balance | | | | 0.20 | | | | 1.0 | | | 0.0010 | ∘∘ | ∘∘ |
| 97 | | | | | | | | | | | | | | |
| Ex. | Balance | | | | 0.25 | | | | 3.0 | | | 0.0040 | ∘∘ | ∘∘ |
| 98 | | | | | | | | | | | | | | |
| Ex. | Balance | | | | | 0.15 | | | 0.1 | 0.0001 | 0.0001 | 0.0001 | ∘∘ | ∘∘ |
| 99 | | | | | | | | | | | | | | |
| Ex. | Balance | | | | | 0.20 | | | 1.0 | 0.0010 | 0.0100 | 0.0010 | ∘∘ | ∘∘∘ |
| 100 | | | | | | | | | | | | | | |
| Ex. | Balance | | | | | 0.25 | | | 3.0 | 0.0040 | 0.1000 | 0.0040 | ∘∘ | ∘∘∘ |
| 101 | | | | | | | | | | | | | | |

In the test for evaluating the temporal variation prevention effect, with the use of a lead-free solder alloy which has been subjected to heat treatment in the atmosphere at 150° C. for 72 hours, 1000 bumps were formed on the wafer level packages under the same conditions as those in the formation of the bumps in Examples. The case where the number of the defective bumps, which were not formed normally, was 10 or less was marked with one circle. The case where the number of the defective bumps was 5 or less was marked with two circles, and the case where the number of the defective bumps was zero was marked with three circles.

As shown in Table 3, Examples 72 to 101 each including any one or any two or more of Mg, P and Ge in a content of 0.0001 to 0.108% by mass in total were all marked with the single circle or higher with respect to the “temporal variation prevention effect.” In particular, Examples 73, 74, 82, 83, 91 and 92 each including Mg in a content of 0.0010 to 0.0040% by mass, Examples 76, 77, 85, 86, 94 and 95 each including P in a content of 0.0100 to 0.1000% by mass, and. Examples 79, 80, 88, 89, 97 and 98 each including Ge in a content of 0.0010 to 0.0040% by mass were all marked with two circles with respect to the temporal variation prevention effect, and thus improvements in the temporal variation prevention effect were verified. Examples 99 to 101 each including three elements, namely, Ga, P and Ge, were marked with two circles or higher, and thus improvements in the temporal variation prevention effect were verified.

### REFERENCE SIGNS LIST

1 lead-free solder bump joining structure
2 first electronic member
5 second electronic member
4, 7 Cu electrode
10 lead-free solder bump
11, 12 intermetallic compound layer

1-9. (canceled)

10. A lead-free solder bump joining structure that joins a first copper electrode of a first electronic device and a second copper electrode of a second electronic device, thereby to allow electric current to flow therebetween at an electric current density of 0.7×10³ [A/cm²] or more, the lead-free solder bump joining structure comprising:
a lead-free solder bump containing any one or any two or more of Ni, Co, Pd, Au and Pt at 0.03 to 0.32% by mass in total and a balance of Sn and inevitable impurities; and
a first interfacial layer disposed between the lead-free solder bump and the first copper electrode; and
a second interfacial layer disposed between the lead-free solder bump and the second copper electrode,
wherein the first and the second interfacial layers are formed of an intermetallic compound expressed by a molecular formula (Cu, X) ₆Sn₅, wherein X indicates any one or any two or more of Ni, Co, Pd, Au and Pt, and have an average thickness of 0.4 [μm] or more and 1.2 [μm] or less.

11. The lead-free solder bump joining structure according to claim 10, wherein the X includes Ni and any one or any two or more of Co, Pd, Au and Pt.

12. The lead-free solder bump joining structure according to claim 10, wherein the X is any one or any two or more of Co, Pd, Au and Pt and excludes Ni.

13. The lead-free solder bump joining structure according to claim 10, wherein the lead-free solder bump includes any one or any two or more of Ag, Cu and Bi in a content of 0.1 to 7.0% by mass in total.

14. The lead-free solder bump joining structure according to claim 10, wherein the lead-free solder bump further includes any one or any two of Mg, P and Ge in a content of 0.0001 to 0.108% by mass in total.

15. The lead-free solder bump joining structure according to claim 10, wherein a content of Fe in the lead-free solder bump is equal to or less than a detection limit of ICP (Inductively Coupled. Plasma) analysis.

16. The lead-free solder bump joining structure according to claim 10, wherein the Sn is a low α-ray Sn that emits α-rays at an α-ray dose of 1 [cph/cm²] or less.

17. The lead-free solder bump joining according to claim 10, wherein the X is any one or two of Au and Pt,
